(19) United States
(12) Patent Application Publication
(10) Pub. No.: US 2010/0252107 A1
(43) Pub. Date: Oct. 7, 2010

(54) SOLAR CELL MODULE

(75) Inventor: Yoshinori Suga, Mishima-shi (JP)

Correspondence Address: GIFFORD, KRASS, SPRINKLE,ANDERSON & CITKOWSKI, P.C, PO BOX 7021, TROY, MI, 48007-7021, US

(73) Assignee: Toyota Jidosha Kabushiki Kaisha, Toyota-Shi (JP)

(21) Appl. No.: 12/716,589

(22) Filed: Mar. 3, 2010

(30) Foreign Application Priority Data
Apr. 2, 2009 (JP) JP2009-090321

(51) Int. Cl. H01L 31/00

(52) U.S. Cl. 136/259

(57) ABSTRACT

A solar cell module includes: a reflector; a encapsulant that includes a first corrugated portion that corresponds to a corrugated shape of the reflector; and a solar cell that is encapsulated in the encapsulant, wherein the encapsulant is fixed to the reflector and the solar cell; and at least one of a surface of the encapsulant fixed to the reflector and a surface of the encapsulant fixed to the solar cell is provided with a second corrugated portion that has a smaller protrusion than a protrusion of the first corrugated portion.

### INCORPORATION BY REFERENCE

The disclosure of Japanese Patent Application No. 2009-090321 filed on Apr. 2, 2009 including the specification, drawings and abstract is incorporated herein by reference in its entirety.

### BACKGROUND OF THE INVENTION

1. Field of the Invention

The present invention relates to a solar cell module that includes a reflector.

2. Description of the Related Art

As a related art in this field, there is Japanese Patent Application Publication No. 2001-148500 (JP-A-2001-148500). A solar cell module described in this publication includes a bifacial solar cell, in which sunlight that passes gaps between solar cells is reflected by a reflector and introduced to a back surface of the solar cell. In order to increase the incident light, a solar cell described in Japanese Patent Application Publication No. 11-307791 (JP-A-11-307791) is provided with a corrugated translucent sheet (reflector) made of ethylene-vinyl acetate (EVA) copolymer. In the solar cell module with such a structure, the sunlight that passes through the gaps between the neighboring solar cells can efficiently be utilized, so that the power generation efficiency is improved.

However, in the solar cell module of the related art described above, because the material used for the reflector and the solar cell and the material used for the encapsulant layer are different, the solar cell and the reflector are easily separated from the encapsulant layer. The separation from the encapsulant layer allows air and moisture to intrude, thereby reducing the long-term reliability and power generation efficiency. Additionally, bubbles may easily be formed between the reflector and the encapsulant layer or between the solar cell and the encapsulant layer during the manufacturing process of the solar cell module. For this reason, the long-term reliability and power generation efficiency are also reduced.

### SUMMARY OF THE INVENTION

The present invention provides a solar cell module that can maintain long-term reliability and that minimizes losses in power generation efficiency over a long period of time.

An aspect of the present invention relates to a solar cell module. The solar cell module includes: a reflector; an encapsulant that includes a first corrugated portion that corresponds to a corrugated shape of the reflector; and a solar cell that is encapsulated in the encapsulant, wherein the encapsulant is fixed to the reflector and the solar cell, and at least one of a surface of the encapsulant fixed to the reflector and a surface of the encapsulant fixed to the solar cell is provided with a second corrugated portion that has a smaller protrusion than a protrusion of the first corrugated portion.

In this type of solar cell module, since the first corrugated portion of the encapsulant corresponds to the corrugated shape of the reflector, the encapsulant can easily be brought into contact with the reflector. Also, since the reflector is provided with the first corrugated portion, a larger amount of sunlight can be gathered in the solar cell. When the surface of the encapsulant fixed to the reflector is provided with the second corrugated portion, as the second corrugated portion is easily deformed by a creep phenomenon, the encapsulant can rigidly be fixed to the reflector for a long period of time. Regardless of the material difference between the reflector and the encapsulant, the reflector is hardly separated, and the entry of air and moisture therebetween hardly occurs. Thus, long-term reliability can be maintained, and power generation efficiency may be prevented from falling for a long period of time. Furthermore, when vacuum suction is performed during module forming, the air between the reflector and the encapsulant can be released through the groove of the second corrugated portion. Thus, bubbles are not formed. Furthermore, by the buffering effect of the second corrugated portion, the reflector does not receive a local load during the manufacturing process of the solar cell module. Thus, a local deformation of the reflector may be prevented. When the surface of the encapsulant fixed to the solar cell is provided with the second corrugated portion, as the second corrugated portion is easily deformed by the creep phenomenon, the encapsulant can rigidly be fixed to the solar cell for a long period of time. Regardless of the differences in the material used to form the solar cell and the encapsulant, the solar cell is hardly separated, and the intrusion of the air and moisture hardly occurs. Therefore, the long-term reliability is maintained, and decreases in the power generation efficiency are minimized for a long period of time. Furthermore, when vacuum suction is performed during module forming, the air between the solar cell and the encapsulant layer may be released through the groove of the second corrugated portion. Thus, bubbles are not formed. Furthermore, by the buffering effect of the second corrugated portion, the solar cell does not receive a local load during the manufacturing process of the solar cell module. Thus, fracturing of the solar cell may be prevented.

The present invention makes it possible to maintain the long-term reliability and to prevent the power generation efficiency from falling for a long period of time.

### BRIEF DESCRIPTION OF THE DRAWINGS

The foregoing and further features and advantages of the invention will become apparent from the following description of example embodiments with reference to the accompanying drawings, wherein like numerals are used to represent like elements and wherein:

FIG. 1 is a cross section of a solar cell module according to a first embodiment of the present invention;

FIG. 2 is a perspective view of a first encapsulant layer shown in FIG. 1;

FIG. 3A to FIG. 3C are cross sections of the solar cell module that illustrate the method of manufacturing the solar cell module;

FIG. 4 is a perspective view of the first encapsulant layer of the solar cell module according to a second embodiment of the present invention;

FIG. 5A and FIG. 5B are enlarged cross sections that show a main portion of a reflector;

FIG. 6 is a cross section of the solar cell module according to a third embodiment of the present invention;

FIG. 7 is a perspective view of a first sealing part shown in FIG. 6;

FIG. 8 is a cross section of the solar cell module according to a fourth embodiment of the present invention;

FIG. 9 is a perspective view of a first encapsulant layer shown in FIG. 8;

FIG. 10 is a cross section of the solar cell module according to a fifth embodiment of the present invention;

FIG. 11 is a plan view of the solar cell module shown in FIG. 10; and

FIG. 12 is a perspective view of a first encapsulant layer shown in FIG. 10.

### DETAILED DESCRIPTION OF EMBODIMENTS

Hereinafter, a solar cell module according to the first to fifth embodiments of the present invention is described in detail with reference to accompanying drawings. In the description of the second to fifth embodiments, the same components as those in the first embodiment are denoted by the same symbols, and the descriptions thereof are not repeated.

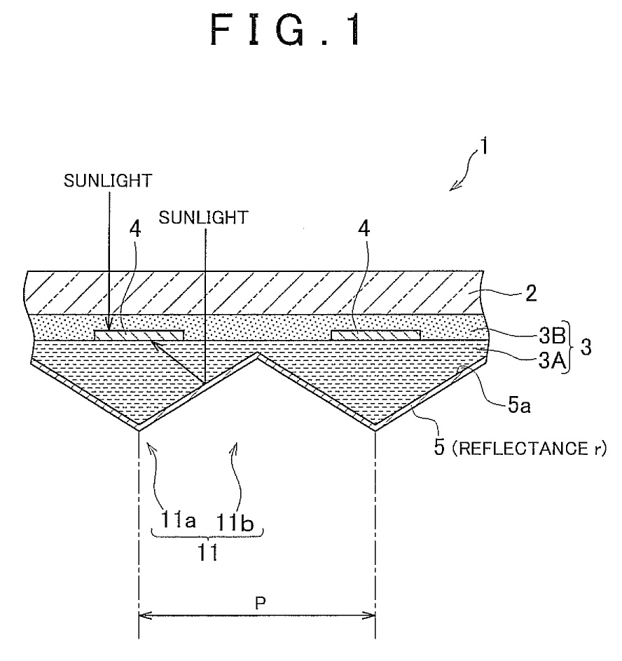

A concentrator solar cell module 1 shown in FIG. 1 may be disposed on the roof of an automobile or a house, and generates electricity by the high-efficiency photovoltaic effect. The solar cell module 1 includes a transparent sheet 2 that allows the sunlight to pass through. The transparent sheet 2 is made of, for example, soda glass, borosilicate glass, silica glass, polycarbonate, acrylic resin, or reinforced white sheet glass. The transparent sheet 2 may be made of reinforced white sheet glass in consideration of strength, heat resistance, long-term reliability, and cost.

Bifacial solar cells 4 may be arranged in a matrix are enclosed in a encapsulant 3 that is fixed to the transparent sheet 2. Examples of a material used for the encapsulant 3 include ethylene-vinyl acetate copolymer (EVA), polyethylene, polyvinyl butyral, polyarylate, and norbornene series cyclic polyolefin.

The cell 4 may be single crystal Si cell, multicrystalline Si cell, thin-film Si cell, III-V cell, compound cell, or organic cell. The cells 4 are spaced uniformly, and each cell 4 is fixed to both ends of a nickel-plated copper interconnector of 2 mm width, by a lead-free solder. Then, the cells 4 are electrically connected in series or parallel. In this way, a solar cell string in the shape of a ladder is formed.

A reflector 5, whose cross section is in the convex shape, is fixed to the back side of the encapsulant 3 so as to face the transparent sheet 2 disposed on a front side of the encapsulant 3. The reflector 5 has a corrugated cross-section. In consideration of press forming, long-term reliability, and cost, the reflector 5 may be made of a metal sheet or plastic sheet, as a substrate on which a reflective coating of silver or aluminum is deposited. In order to form a corrugated portion 11 on the reflector 5, for example, a biaxially stretched polyethylene terephthalate film (with thickness of 25 μm) on which silver is deposited (with coating thickness of 900 nm) is attached to a surface of a 0.2 mm thick aluminum sheet, and then the corrugated portion 11 is formed on the reflector 5 by sheet-metal working. Here, silver-palladium, silver-gold, silver-platinum, etc. may be used for silver deposition in order to enhance the resistance to oxidation. Furthermore, the silver-deposited surface may be coated with light curing resin or the like.

By using the reflector 5, sunlight passing between the neighboring solar cells 4 reaches the reflector 5 and is reflected by the reflecting surface 5a of the reflector 5 and then introduced to a back surface of the solar cell 4. Accordingly, the solar cell 4 may then more efficiently generate electricity by receiving the sunlight with both of the front surface and back surface of the solar cell 4.

The encapsulant 3 is provided as a film that includes a first encapsulant layer 3A that is fixed to the reflector 5, and a second encapsulant layer 3B that is fixed to the transparent sheet 2. In the solar cell module 1, the solar cell 4 is sandwiched between the first encapsulant layer 3A and the second encapsulant layer 3B. The first encapsulant layer 3A and the second encapsulant layer 3B are formed as a film by a heated roller through an extrusion molding process using, for example, a T-die.

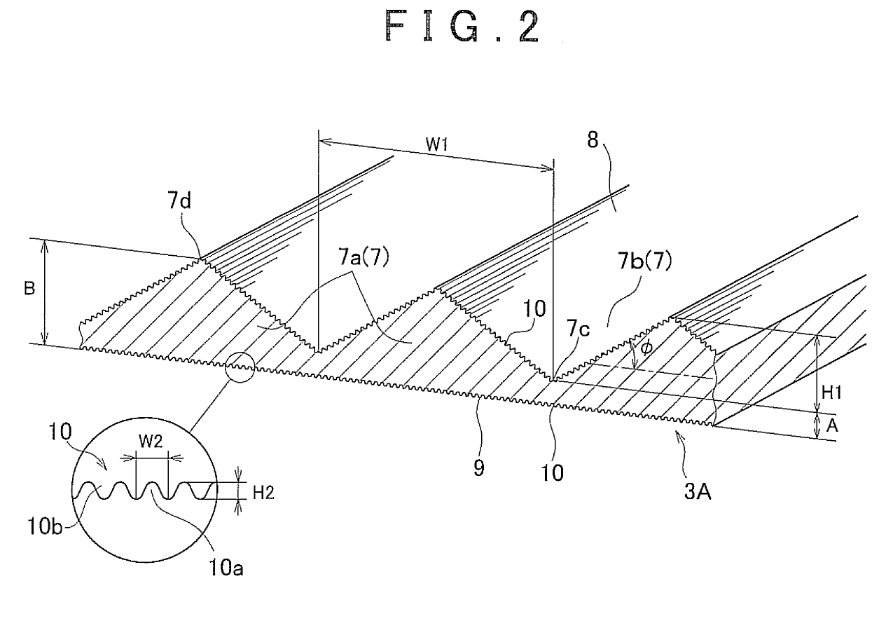

As shown in FIG. 2, the first encapsulant layer 3A includes a first corrugated portion 7 that corresponds to the corrugated portion 11 of the reflector 5. The first corrugated portion 7 is provided with protrusions 7a and grooves 7b that have triangular cross sections. The protrusions 7a and grooves 7b are arranged alternately. The protrusion 7a of the first corrugated portion 7 corresponds to a protrusion 11a, which has a triangular cross section, of the corrugated portion 11 of the reflector 5 shown in FIG. 1. The groove 7b of the first corrugated portion 7 corresponds to a groove 11b, which has a triangular cross section, of the corrugated portion 11 of the reflector 5 shown in FIG. 1.

In the first encapsulant layer 3A, an angular surface 8 that is fixed to the reflector 5 and a flat surface 9 that is fixed to the solar cell 4 are provided with a second corrugated portion 10 that has a smaller protrusion 10a than the protrusion 7a of the first corrugated portion 7. The second corrugated portion 10 in the shape of wave is formed by alternately arranging a protrusion 10a and a groove 10b in a quadric curve manner.

The first encapsulant layer 3A satisfies the following relationships: W2×5<W1, H1/W1>0.3 (or 0.4), and H2/W2>0.3 (or 0.4), where the width and height of the protrusion 7a of the first corrugated portion 7 are indicated by W1 and H1 respectively, and where the width and height of the protrusion 10a of the second corrugated portion 10 are indicated by W2 and H2, respectively.

In the solar cell module 1, because the first corrugated portion 7 of the first encapsulant layer 3A corresponds to the corrugated portion 11 of the reflector 5, the first encapsulant layer 3A may easily be brought into contact with the reflector 5. Also, the first corrugated portion 7 on the reflector 5 improves the light gathering capability of the solar cell 4.

In the first encapsulant layer 3A, when the second corrugated portion 10 is provided on the angular surface 8 that is fixed to the reflector 5, as the second corrugated portion 10 is easily deformed by the creep phenomenon, the first encapsulant layer 3A is brought into contact with the reflector 5 for a long period of time. Regardless of the material difference between the reflector 5 and the encapsulant layer 3A, the reflector 5 is hardly separated from the encapsulant layer 3A, and the air and moisture hardly enter therebetween. Therefore, the long-term reliability can be maintained, and the reduction in power generation efficiency can be prevented for a long period of time.

Moreover, when vacuum suction is performed during module forming, the air between the reflector 5 and the first encapsulant layer 3A can be released through the groove 10b of the second corrugated portion 10. Thus, accumulation of the air can be prevented. Furthermore, by the buffering effect of the second corrugated portion 10, the reflector 5 is insulated from local shocks during the manufacturing process of the solar cell module 1. Thus, a local deformation of the reflector 5 can be prevented.

In the first encapsulant layer 3A, when the second corrugated portion 10 is provided on the flat surface 9, as the second corrugated portion 10 is easily deformed by the creep phenomenon, the first encapsulant layer 3A may be brought into contact with the solar cell 4 for a long period of time. Regardless of the material difference between the solar cell 4 and the first encapsulant layer 3A, the solar cell 4 is hardly separated from the encapsulant layer 3A, and the air and moisture hardly enter therebetween. Therefore, the long-term reliability can be maintained, and the reduction in power generation efficiency can be prevented for a long period of time.

Moreover, when vacuum suction is performed during module formation, the air between the solar cell 4 and the first encapsulant layer 3A may be released through the groove 10b of the second corrugated portion 10. Thus, accumulation of the air can be prevented. Furthermore, by the buffering effect of the second corrugated portion 10, the solar cell 4 is insulated from local shocks during the manufacturing process of the solar cell module 1. Thus, the solar cell can be prevented from fracturing.

In the first encapsulant layer 3A, when the thickness of the first encapsulant layer 3A at the bottom 7c of the groove 7b of the first corrugated portion 7 is indicated by A, and when the thickness of the first encapsulant layer 3A at the peak 7d of the protrusion 7a of the first corrugated portion 7 is indicated by B, the relationship “A×2<B” is satisfied.

With such structure, the bottom 7c of the first corrugated portion 7 may be arranged close to the solar cell 4. As a result, because the reflector 5 may be arranged close to the solar cell 4, the sunlight reflected by the reflector 5 can efficiently be gathered in the solar cell 4. By thinning the first encapsulant layer 3A, fewer bubbles are generated from the first encapsulant layer 3A during module formation, and the residual strain of the reflector 5 and the solar cell 4 caused by pressure-bonding of the first encapsulant layer 3A is also reduced. During the module formation, when the first encapsulant layer 3A is thick, the first encapsulant layer 3A tends not to be heated evenly. However, when the first encapsulant layer 3A is thin, the first encapsulant layer 3A can be heated evenly, and the uniform and contact with the reflector 5 and solar cell 4 can be obtained.

The first encapsulant layer 3A that is made of ethylene-vinyl acetate copolymer (EVA) may have the dimension of, for example, W1=15 mm, H1=6 mm, W2=0.5 mm, H2=0.4 mm, A=1 mm, B=7 mm. An inclined surface may have an inclination angle Φ=38.7°.

By adopting the first encapsulant layer 3A described above, productivity of the solar cell module 1 can be improved. And by the improvement of light gathering capability, as an amount of the light that escapes from the transparent sheet 2 is reduced, glare of the solar module 1 can be reduced, and the appearance can be improved. The module 1 does not easily form bends or curves even after long time use. Furthermore, soldered places of the solar cell string, in which the plurality of solar cells 4 are arranged in parallel, do not easily receive stress. The improvement in contact reduces loss of light caused by diffused reflection interfaces between the first encapsulant layer 3A and the reflector 5 and at interfaces between the first encapsulant layer 3A and the solar cell 4.

In order to obtain high power generation efficiency, the cross sectional shape of the reflector 5 needs to be determined precisely, and the positional relationship between the solar cell 4 and the reflector 5 needs to be fixed. However, it has been difficult in the related technical field to obtain, the positional precision required for a practical solar cell module. According to the present invention, by the buffering effect of the second corrugated portion 10, the reflector 5 does not easily receive a local load during the manufacturing process of the solar cell module 1. Since a local deformation of the reflector 5 can be prevented, the positional precision of the reflector 5 can be obtained highly accurately.

Furthermore, in the present invention, the inclination angle Φ (refer to FIG. 2) of the inclination surface, which is formed in the first corrugated portion 7 and which contributes to light gathering, may be determined in the following way.

In the solar cell module equipped with a bifacial solar cell shown in FIG. 1, the inclination angle Φ of the inclination surface is expressed by the following equation where light gathering power is indicated by “a”, reflectance of the reflector 5 is indicated by “r”, and a cell arrangement pitch is indicated by “P”.

$$Ω ( θ ) = \frac{1 - r}{a} + \frac{r}{P} \cdot \frac{\begin{matrix}a \cdot t \cdot tan 2 θ + a \cdot P \cdot \\ tan 2 θ \cdot sin θ + P\end{matrix}}{a \cdot ( 1 + tan 2 θ \cdot tan θ )} \qquad [ Equation 1 ]$$

The reflector angle that produces the maximum optical efficiency Ωmax is indicated by θmax in the function Ω(θ) in which 0=0° to 90°. In this case, the inclination angle Φ may be set to satisfy the relationship: θmax−15°≦Φ≦θmax+15°. Preferably, the inclination angle Φ may be set to satisfy the relationship: θmax−10°≦Φ≦θmax+10°. More preferably, the inclination angle Φ may be set to satisfy the relationship: θmax−7°≦Φ≦θmax+7°.

The incident light energy I(Z, 0), which hits a light gathering device (single solar cell) in the bifacial solar cell that is inclined to an angle optimal at astronomical noon, is expressed by the following equation where an elevation angle of incident sunlight is indicated by Z, the incident light energy that hits an unit region of the transparent sheet with consideration of Fresnel loss is indicated by i(Z), and an inclination angle of the reflector is indicated by θ.

$$I ( Z , θ ) = 2 \cdot i ( Z ) \cdot [ \begin{matrix}\frac{P}{2 a} + r \cdot \\ \{ \frac{1}{2} \cdot \frac{\begin{matrix}a \cdot t \cdot tan 2 θ + a \cdot P \cdot \\ tan 2 θ \cdot sin θ + P\end{matrix}}{a \cdot ( 1 + tan 2 θ \cdot tan θ )} - \frac{P}{2 a} \}\end{matrix} ] \qquad [ Equation 2 ]$$

Here, the cell arrangement pitch is indicated by P, the light gathering power is indicated by “a”, and the reflectance of the reflector is indicated by “r”. Total integral strength Iₜₒₜ of the light energy that is radiated from the sun in the daytime and that reaches the cell is expressed by the following equation.

$${I}_{tot} = 2 \cdot {\int }_{0}^{π} i ( Z ) \cdot \{ \begin{matrix}( 1 - r ) \frac{P}{2 a} + \frac{r}{2} \cdot \\ \frac{\begin{matrix}a \cdot t \cdot tan 2 θ + a \cdot P \cdot \\ tan 2 θ \cdot sin θ + P\end{matrix}}{a \cdot ( 1 + tan 2 θ \cdot tan θ )}\end{matrix} \} d Z \qquad [ Equation 3 ]$$

In a standard solar cell module in which no light gathering device is provided, total integral strength I_{noc} of the light energy that reaches the cell per the same module area is expressed by the following formula.

$${I}_{noc} = P \cdot {\int }_{0}^{π} i ( Z ) \cdot d Z \qquad [ Equation 4 ]$$

Therefore, optical efficiency is expressed by the following equation.

$$Ω ( θ ) = \frac{{I}_{tot}}{{I}_{noc}} = \frac{1 - r}{a} + \frac{r}{P} \cdot \frac{\begin{matrix}a \cdot t \cdot tan 2 θ + a \cdot P \cdot \\ tan 2 θ \cdot sin θ + P\end{matrix}}{a \cdot ( 1 + tan 2 θ \cdot tan θ )} \qquad [ Equation 5 ]$$

Accordingly, at the reflector's inclination angle that maximizes the value of Ω(θ), the light gathering efficiency reaches the highest level. In practical use, the inclination angle of the reflector is determined in consideration of various restrictions such as a setting angle, a setting direction, and appearance. Thus, the inclination angle Φ of the reflector in the present invention is set to satisfy the relationship: θmax−15°≦Φ≦θmax+15° where θmax represents the reflector angle that produces maximum value Ωmax in the function Ω (θ) in which θ is between 0° and 90°. In order to improve conversion efficiency in the area having much direct sunlight, the inclination angle Φ of the reflector may be set to satisfy the relationship: θmax−10°≦Φ≦θmax+10°. In order to realize the high conversion efficiency including diffused luminous flux, the inclination angle Φ of the reflector may be set to satisfy the relationship: θmax−7°≦Φ≦θmax+7°.

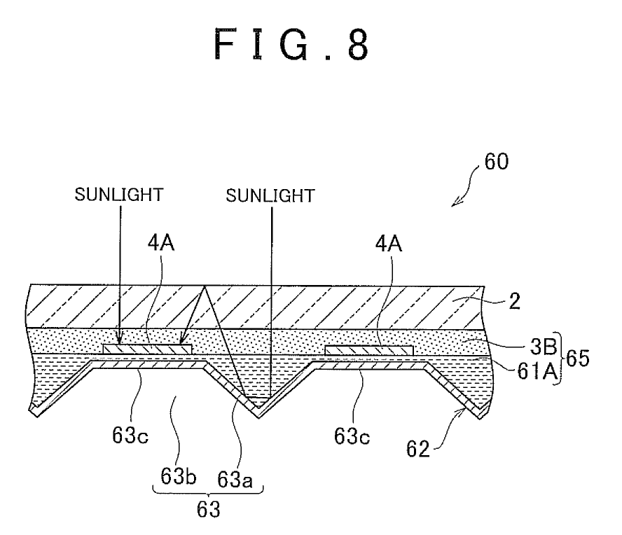

As shown in FIG. 8, in the concentrator solar cell module that uses a monofacial solar cell, total reflection on the surface of the transparent sheet is used more actively. Accordingly, the value Φ for the monofacial solar cell is preferably set about 8 degrees smaller than the value Φ for the bifacial solar cell. The inclination angle Φ of the reflector may be set to satisfy the relationship: θmax−23°≦Φ≦θmax+7° where θmax represents the reflector angle that produces the maximum value Ωmax in the function Ω(θ) in which θ is between 0° and 90°. In order to improve the conversion efficiency in the area having much direct sunlight, the inclination angle Φ of the reflector may be set to satisfy the relationship: θmax−18°≦Φ≦θmax+2°. In order to realize the high conversion efficiency including diffused luminous flux, the inclination angle Φ of the reflector may be set to satisfy the relationship: θmax−15°≦Φ≦θmax−1°.

Next, a method of manufacturing the concentrator solar cell module 1 with such structure is described.

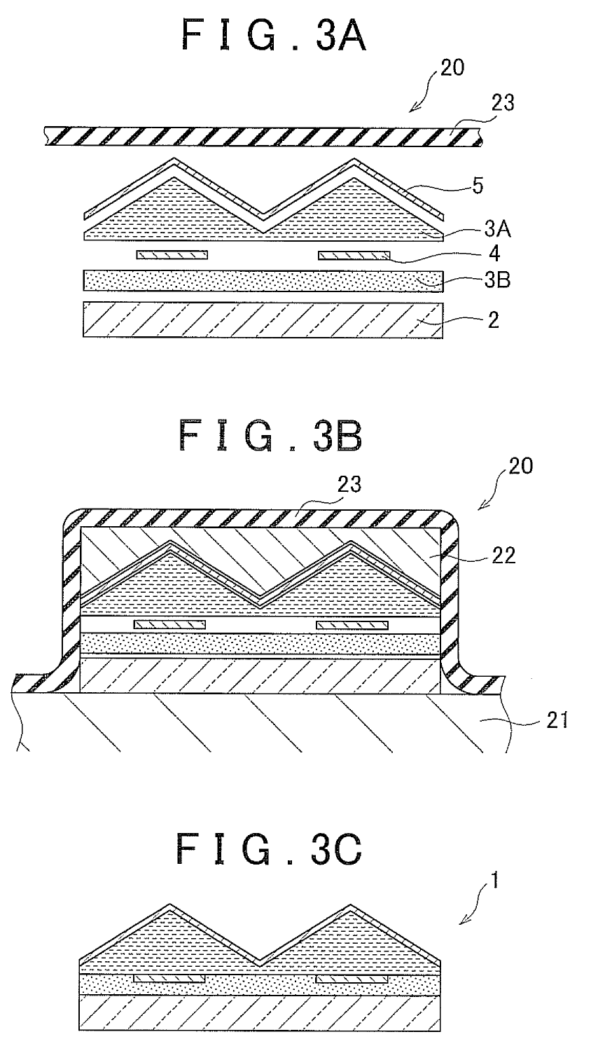

As shown in FIG. 3A to FIG. 3C, on a heating plate 21 of a laminating machine 20, the transparent sheet 2, the second encapsulant layer 3B, the string of the solar cells 4, the first encapsulant layer 3A, and the reflector 5 are mounted in the stated order. Furthermore, a shape-retaining die 22 that is formed by a milling machine to match the corrugated portion 11 of the reflector 5 is placed above the reflector 5, so that the reflector 5 is not directly pressed by a diaphragm 23.

The solar cell module is heated to 135° C. by the heating plate 21. A vacuum state is created in a cavity between the heating plate 21 and the diaphragm 23. Then, the diaphragm 23 presses the shape-retaining die 22 for 15 minutes. Accordingly, the encapsulant layers 3A and 3B that are softened in the laminating machine 20 are pressure-bonded to the transparent sheet 2, the solar cell 4, and the reflector 5.

By using the shape-retaining die 22 made of light weight aluminum, the reflector 5 is firmly positioned in the laminating machine 20, so that rubbing between the first encapsulant layer 3A and the reflecting surface 5a of the reflector 5 is prevented. Thus, the vulnerable reflecting surface 5a is not damaged, and the quality of the reflecting surface 5a is maintained. Therefore, diffused reflection caused by the damage does not easily occur on the reflecting surface 5a, so that high efficiency photoelectric conversion can be obtained in the cell 4.

In addition, because the inclination angle of the reflector 5 is accurately maintained by the shape-retaining die 22, the solar cell module 1 with high light gathering capability may be manufactured with high yields. Because the manufacturing process is simple, the solar cell module 1 may be manufactured at low cost.

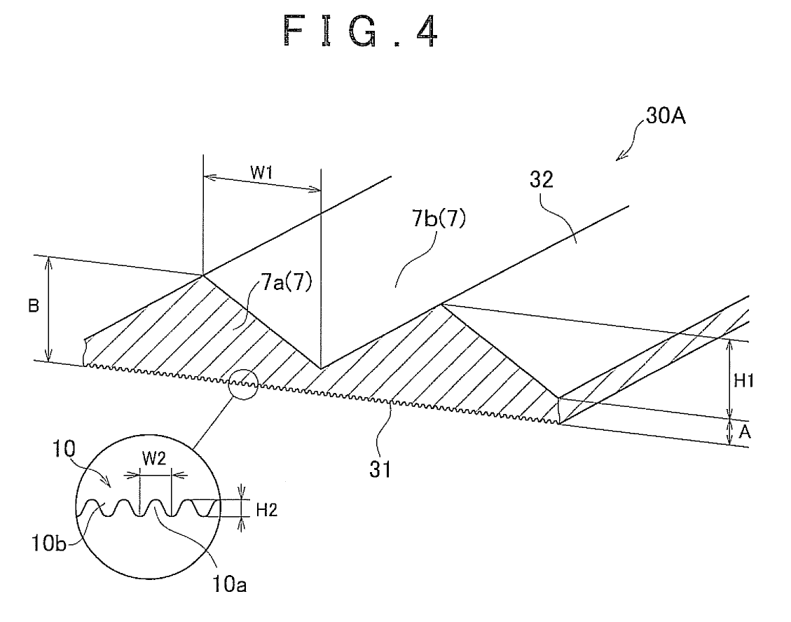

As shown in FIG. 4, the solar cell module according to the second embodiment is provided with a first encapsulant layer 30A. In the first encapsulant layer 30A, a flat surface 31, which is fixed to the solar cell 4, is provided with the second corrugated portion 10. However, an angular surface 32, which is fixed to a reflector 34, is not provided with the second corrugated portion 10.

The first encapsulant layer 30A, which is made of transparent polyethylene resin, may have the dimension of, for example, W1=12 mm, H1=4.8 mm, W2=0.4 mm, H2=0.3 mm, A=0.7 mm, and B=5.5 mm.

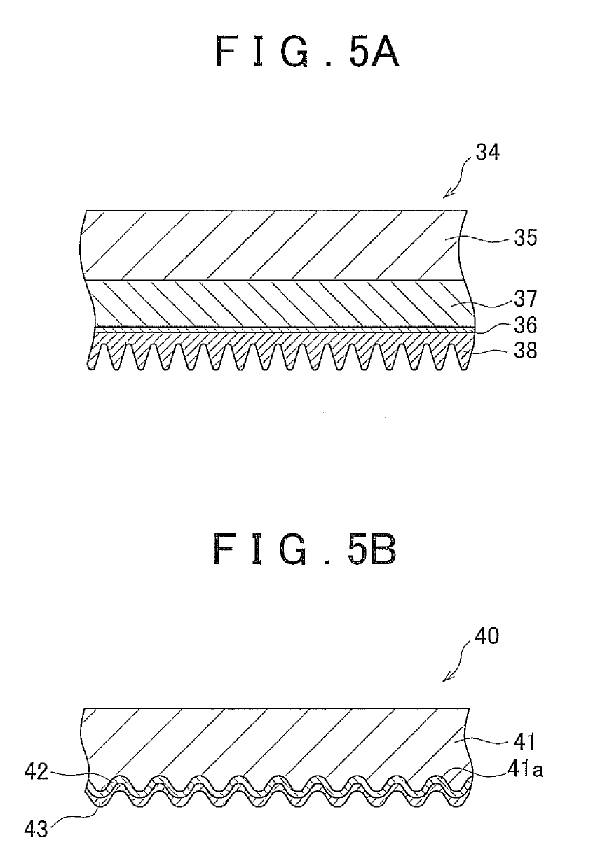

As shown in FIG. 5A, the reflector 34, which is fixed to the first corrugated portion 7 shown in FIG. 4, is provided with a metal substrate 35 made of aluminum, brass, stainless, etc. To the metal substrate 35, biaxially stretched polyethylene terephthalate film 37 that has deposited silver layer 36 is attached. To the deposited silver layer 36, a bonding layer 38 that is formed in the wavy shape by transparent light curing resin is attached.

When the bonding layer 38 of the reflector 34 is fixed to the angular surface 32 of the first encapsulant layer 30A by the laminating machine 20, the bonding strength between the bonding layer 38 and the angular surface 32 is increased to the level that endures the large temperature change, thanks to the corrugated shape of the bonding layer 38.

As shown in FIG. 5B, the reflector 40 includes a metal substrate 41 that is made of aluminum, brass, stainless, etc. The surface 41a of the metal substrate 41 is shaped into a corrugated form by sandblasting or sheet-metal working. A deposited silver layer 42 and a bonding layer 43 that is made of transparent light curing resin are laminated in this order to the surface 41a. The reflector 40 structured as described above can maintain the bonding strength with the first encapsulant layer 30A.

The second embodiment has the same function and effect as the first embodiment.

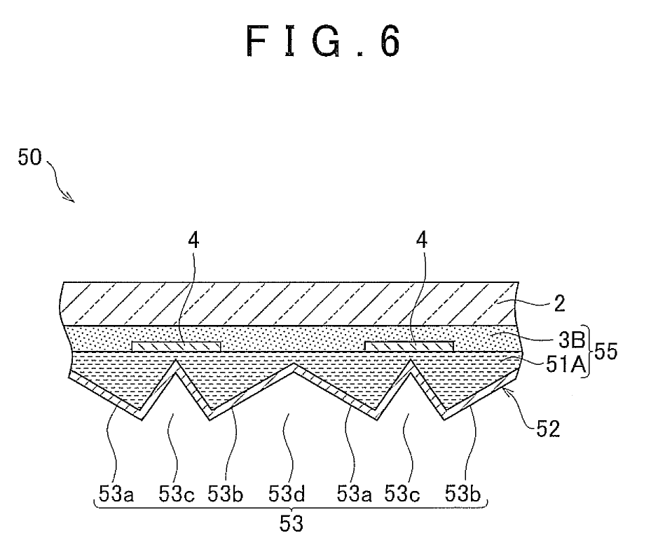

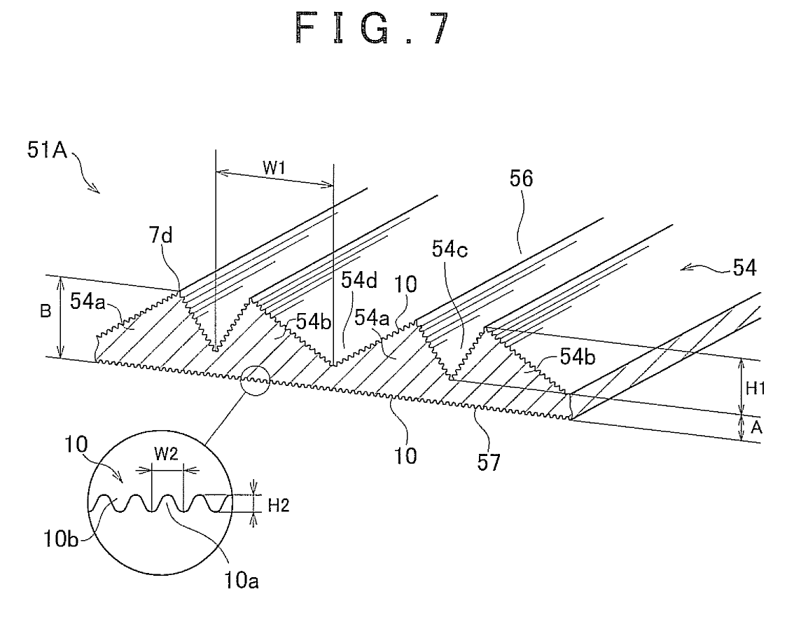

As shown in FIG. 6 and FIG. 7, in a solar cell module 50 according to the third embodiment, a first encapsulant layer 51A of an encapsulant 55 includes a first corrugated portion 54 that corresponds to a corrugated portion 53 of a reflector 52. The corrugated portion 53 of the reflector 52 includes: two pairs of protrusions 53a and 53b that have a triangular cross section and that extend oppositely from the solar cell 4 at the both ends of the solar cell 4; a first groove 53c that is located between the protrusion 53a and the protrusion 53b and that is recessed toward the solar cell 4; and a second groove 53d that is located between the solar cells 4 and that has a triangular cross section.

As shown in FIG. 7, the first corrugated portion 54 of the first encapsulant layer 51A includes: a first protrusion 54a and a second protrusion 54b that correspond to the first protrusion 53a and the second protrusion 53b of the reflector 52 respectively; and a first groove 54c and a second groove 54d that correspond to the first groove 53c and the second groove 53d of the reflector 52 respectively. The heights of the protrusion 54a and the protrusion 54b are the same, and likewise the depths of the groove 54c and the groove 54d are also the same.

In the first encapsulant layer 51A, the second corrugated portion 10 is formed on an angular surface 56 that is fixed to the reflector 52 and on a flat surface 57 that is fixed to the solar cell 4.

The first encapsulant layer 51A satisfies the relationships: W2×5<W1, H1/W1>0.3 (or 0.4), and H2/W2>0.3 (or 0.4), where the width and height of the protrusion 54b of the first corrugated portion 54 are indicated by W1 and H1 respectively, and where the width and height of the protrusion 10a of the second corrugated portion 10 are indicated by W2 and H2 respectively. The same relationships are satisfied for the angular part 54a of the first corrugated portion 54.

The third embodiment has the same function and effect as the first embodiment.

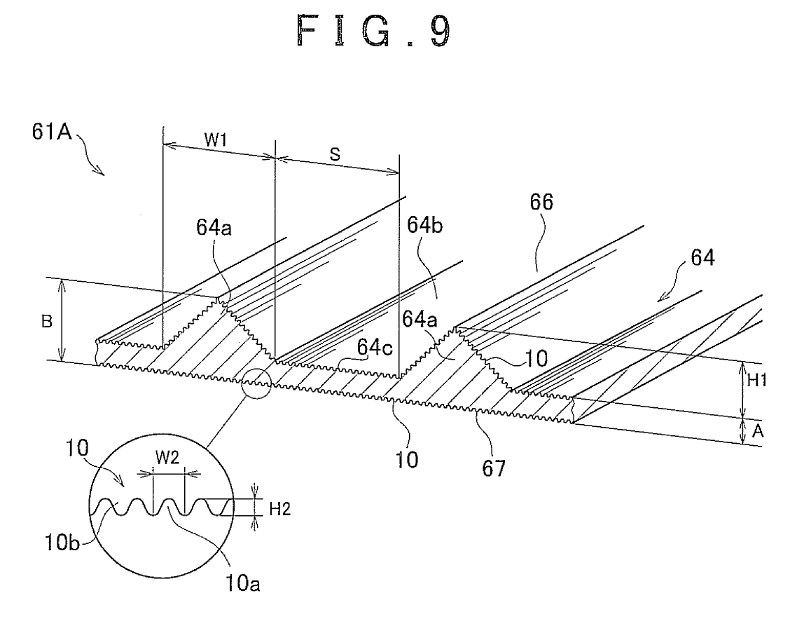

As shown in FIG. 8 and FIG. 9, in a solar cell module 60 according to the fourth embodiment, a first encapsulant layer 61A of an encapsulant 65 includes a first corrugated portion 64 that corresponds to a corrugated portion 63 of a reflector 62. The corrugated portion 63 of the reflector 62 includes: a groove 63b that is recessed in the trapezoidal shape toward the mono-facial solar cell 4A; and a protrusion 63a that is located between the mono-facial solar cells 4A and that has a triangular cross section.

As shown in FIG. 9, the first corrugated portion 64 of the first encapsulant layer 61A includes: a protrusion 64a that corresponds to the protrusion 63a of the reflector 62; and a groove 64b that corresponds to the groove 63b of the reflector 62. Since the solar cell 4A is a monofacial type, a bottom 63c of the reflector 62 faces the solar cell 4A in parallel. Correspondingly, a bottom 64c of the first encapsulant layer 61A faces the solar cell 4A in parallel.

In the first encapsulant layer 61A, the second corrugated portion 10 is formed on an angular surface 66 that is fixed to the reflector 62 and on a flat surface 67 that is fixed to the solar cell 4A.

The first encapsulant layer 61A satisfies the relationships: W2×5<W1, H1/W1>0.3 (or 0.4), and H2/W2>0.3 (or 0.4), where the width and height of the protrusion 64a of the first corrugated portion 64 are indicated by W1 and H1 respectively, and where the width and height of the protrusion 10a of the second corrugated portion 10 are indicated by W2 and H2 respectively.

In a gap G between a light receiving surface of the mono-facial solar cell 4A and a plane of incidence of the transparent sheet 2, the relationship W1/10<G<W1/3 is satisfied.

The first encapsulant layer 61A, which is made of transparent ethylene-vinyl acetate resin, may have the dimension of, for example, W1=12 mm, H1=4.8 mm, W2=0.4 mm, H2=0.3 mm, A=0.7 mm, B=5.5 mm, and the width S of the bottom 64c=20 mm. The dimension of the mono-facial solar cell 4A is 20 mm on the narrow side and 125 mm on the wide side. In the case of the mono-facial type, the inclination angle Φ of the inclined surface may be set smaller than the bifacial type by 8° to 10°, such as Φ=28.1°.

The fourth embodiment has the same function and effect as the first embodiment.

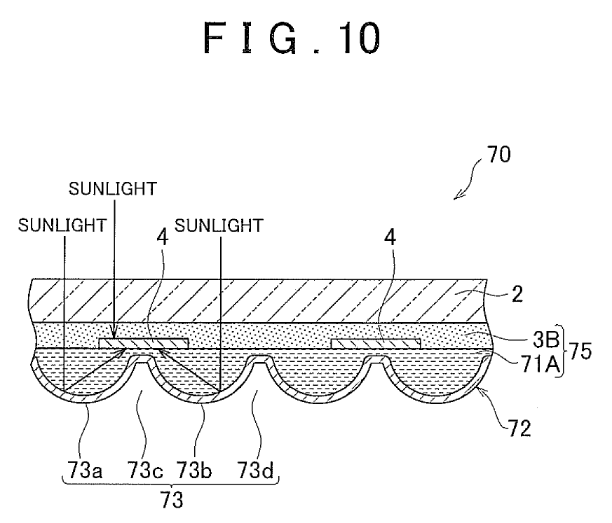

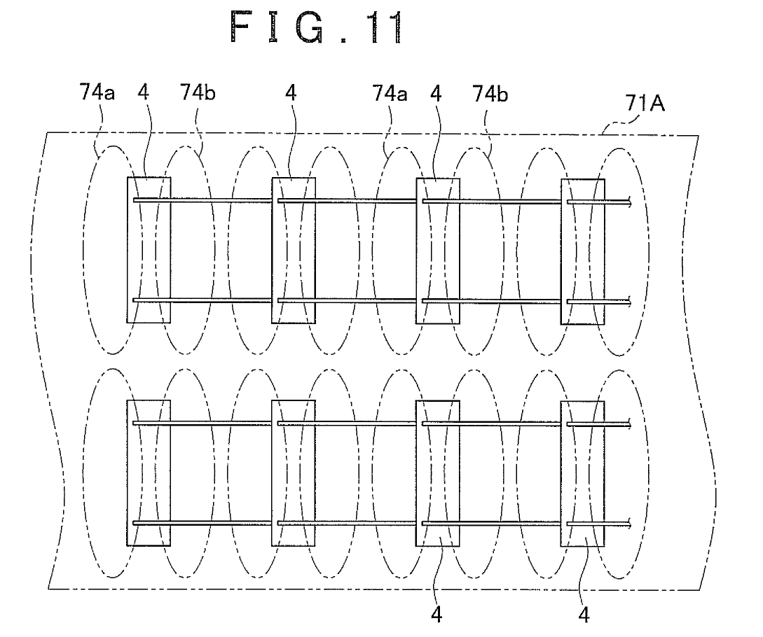

As shown in FIG. 10 to FIG. 12, in a solar cell module 70 according to the fifth embodiment, a first encapsulant layer 71A of an encapsulant 75 includes a first corrugated portion 74 that corresponds to a corrugated portion 73 of a reflector 72. The corrugated portion 73 of the reflector 72 includes: two pairs of protrusions 73a and 73b that have an arcuate cross section and that extend oppositely from the solar cell 4 at the both ends of the solar cell 4; a first groove 73c that is recessed toward the solar cell 4 between the protrusion 73a and the protrusion 73b; and a second groove 73d that is located between the solar cells 4.

The protrusions 73a and 73b of the reflector 72 have a light focusing property like that of an elliptic condenser lens, so that the light reflected by the pair of right and left protrusions 73a and 73b can be gathered to the solar cell 4.

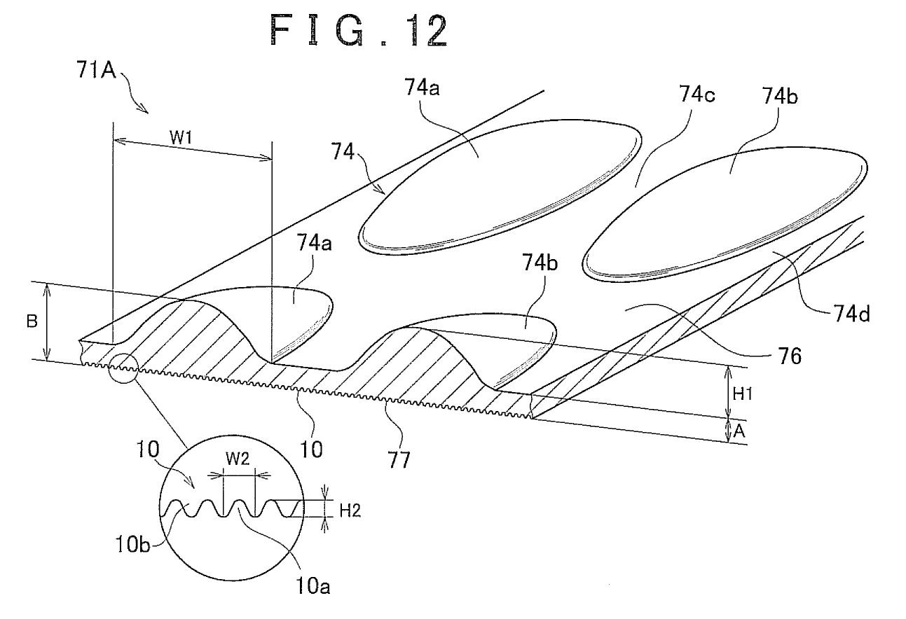

As shown in FIG. 12, the first corrugated portion 74 of the first encapsulant layer 71A includes: protrusions 74a and 74b that correspond to the protrusions 73a and 73b of the reflector 72 respectively; and a first groove 74c and a second groove 74d that correspond to the first groove 73c and the second groove 73d of the reflector 72 respectively. The protrusion 74a and the protrusion 74b are in the same shape, and the groove 74c and the groove 74d are also in the same shape.

In the first encapsulant layer 71A, a flat surface 77 that is fixed to the solar cell 4 is provided with a second corrugated portion 10. However, an angular surface 76 that is fixed to the reflector 72 is not provided with a second corrugated portion 10. Instead, the reflector 72 is formed in the same way as the reflectors 34 and 40 shown in FIG. 5A or FIG. 5B.

The first encapsulant layer 71A satisfies the relationships: W2×5<W1, H1/W1>0.3 (or 0.4), and H2/W2>0.3 (or 0.4), where the width and height of the protrusion 74a of the first corrugated portion 74 are indicated by W1 and H1 respectively, and where the width and height of the protrusion 10a of the second corrugated portion 10 are indicated by W2 and H2 respectively. The same relationships are satisfied for the angular part 74b of the first corrugated portion 74.

The first encapsulant layer 71A, which is made of transparent ethylene-vinyl acetate resin, may have the dimension of, for example, W1=15 mm, H1=6 mm, W2=0.5 mm, H2=0.4 mm, A=0.5 mm, B=6.5 mm.

The protrusions 73a and 73b of the reflector 72 focus light like elliptic condenser lenses so that the light reflected by the pair of right and left protrusions 73a and 73b may be gathered by the solar cell 4. Thus, by using the reflector 72 with improved light focusing property, the size of each solar cell 4 may be reduced, so that the space between the cells 4 in the string can be increased. Because each solar cell 4 may be reduced in size, the weight of the solar cell module 70 is also reduced.

The fifth embodiment has the same function and effect as the first embodiment.

It is understood that the present invention is not limited to the above embodiments. For example, the second encapsulant layer 3B may be provided with the second corrugated portion 10.

What is claimed is:

1. A solar cell module comprising:
a reflector;
an encapsulant that includes a first corrugated portion that corresponds to a corrugated shape of the reflector; and
a solar cell that is encapsulated in the encapsulant, wherein:
the encapsulant is fixed to the reflector and the solar cell; and
at least one of a surface of the encapsulant fixed to the reflector and a surface of the encapsulant fixed to the solar cell is provided with a second corrugated portion that has a smaller protrusion than a protrusion of the first corrugated portion.

2. The solar cell module according to claim 1, wherein the encapsulant is formed to satisfy the following equations:
W2×5<W1
H1/W1>0.3
H2/W2>0.3,
where W1 is a width of the protrusion of the first corrugated portion, H1 is a height of the protrusion of the first corrugated portion, W2 is a width of the protrusion of the second corrugated portion, and H2 is a height of the protrusion of the second corrugated portion.

3. The solar cell module according to claim 1, wherein, the encapsulant is formed to satisfy the following equations:
W2×5<W1
H1/W1>0.4
H2/W2>0.4,
where W1 is a width of the protrusion of the first corrugated portion, H1 is a height of the protrusion of the first corrugated portion, W2 is a width of the protrusion of the second corrugated portion, and H2 is a height of the protrusion of the second corrugated portion.

4. The solar cell module according to claim 1, wherein, a thickness of the encapsulant at the peak of the protrusion of the first corrugated portion is more than twice a thickness of the encapsulant on the bottom of a groove of the first corrugated portion.

5. The solar cell module according to claim 1, wherein the second corrugated portion is formed on a surface of the encapsulant that is fixed to the solar cell, and a surface of the reflector that is fixed to the encapsulant is provided with a third corrugated portion that has a smaller protrusion than the protrusion of the first corrugated portion.

6. The solar cell module according to claim 5, wherein the reflector comprises: a metal substrate; a film that is attached to the metal substrate and on which a layer of silver is deposited; and a bonding layer, which is attached to the deposited silver layer and on which the third corrugated portion is formed by transparent resin.

7. The solar cell module according to claim 5, wherein:
the reflector comprises a metal substrate and a bonding layer, formed from transparent resin, that is attached to the metal substrate; and
the metal substrate has a corrugated surface.
